(19) United States
(12) Patent Application Publication
(10) Pub. No.: US 2006/0282750 A1
(43) Pub. Date: Dec. 14, 2006

(54) Interfacing device and communication control method

(75) Inventor: Junichi Takeuchi, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/440,070

(22) Filed: May 25, 2006

(30) Foreign Application Priority Data
May 27, 2005 (JP) 2005-156074

(51) Int. Cl. H03M 13/00

(52) U.S. Cl. 714/776

(57) ABSTRACT

Disclosed is a system including a plurality of node devices connected to a network, in which in the node device, each transmit a packet for transferring noise information so that any of the node devices on the network is able to grasp the noise information. The signal level of a received signal from a transmission line is monitored by a monitor circuit and analyzed by a sampling analysis unit. Based on the result of analysis, a packet for transferring noise information is generated by a noise information transfer packet generator and controlling unit and the generated packet is sent out from an output circuit to a transmission line. On receipt of the packet for transferring noise information, sent over the transmission line, the controlling unit extracts the noise information from the packet to supply the extracted noise information to a correction command circuit.

### FIELD OF THE INVENTION

This invention relates to a bus system and, more particularly, to an interfacing device and an interfacing method that may be applied with advantage to a serial bus for e.g. an IEEE1394 serial bus as used in digital equipment exemplified by PCs (personal computers) or digital home electronic devices.

### BACKGROUND OF THE INVENTION

In a high-speed serial network, formed by a serial interface, such as IEEE1394 serial interface, the operation may be destabilized by noise on a cable line. For example the destabilization of the network operation may occur in a noisy environment, such as in a plant. The technique of suppressing noise may directly be applied to a cable, such as by shielding a cable. The technique of shielding the cable is costly, though. In particular, it is difficult to aim at perfection in applying a noise countermeasure on a high speed transmission cable.

FIG. 7 is a diagram showing a typical configuration of an interfacing device for carrying out data transmission/reception to/from transmission lines. Referring to FIG. 7, this interfacing device includes an application-side upper layer logic 201, a data transmit/receive logic 202 for controlling data transmission/reception, an output circuit 203 and an input circuit 204. The data transmit/receive logic 202 receives transmit/receive request issued from the upper layer logic 201 and returns response for transmit/receive request to upper layer logic 201. A plural number of node devices, sometimes referred to hereinafter as devices, each of which is configured as shown in FIG. 7, are interconnected, as shown in FIGS. 8A to 8D, to provide for peer-to-peer communication or communication over a network.

In FIG. 8A, peer-to-peer duplex communication between node devices A and B is achieved.

In FIG. 8B, communication over a network among node devices C, D and E is achieved.

In FIG. 8C, peer-to-peer simplex communication between node devices F and G is achieved.

In FIG. 8D, looped communication among node devices H, I and J is achieved.

Meanwhile, in Patent Document 1, there is disclosed a transmission system capable of reliably deleting a malfunctioning frame, in which different nodes are connected via a transmission line to permit data transmission and data reception among the different nodes. Each node includes a transmission line interface for receiving a communication frame from a transmission line and for sending transmission data as a communication frame to a transmission line. Each node also includes a circulating data processing unit for incrementing and thereby updating a circulating processing identifier in a received frame, determining whether or not the value of the identifier has reached a preset value, and for determining whether or not a frame in question is a malfunctioning frame circulating on a transmission line without being deleted. Each node further includes a transmission/reception processing unit for executing transmission process by appending a circulating processing identifier to transmission data requested to be transmitted by an upper protocol processing unit, executing receive process by processing received data addressed to an own node, and also repeating received data not addressed to the own node to a downstream side while repeating of the malfunctioning frame is stopped.

In case the noise, such as random noise, is present on a transmission line, as shown schematically in FIGS. 8A to 8D, a received signal become destabilized to render normal transmission difficult. If large noise is present on a transmission line, received data errors are continued. Hence, a circulating data processing unit such as is proposed in Patent Document 1, is effective from the perspective of network management.

[Patent Document 1]

Japanese Patent Kokai Publication No. JP-A-11-32067

### SUMMARY OF THE DISCLOSURE

However, with the conventional system of, for example, Patent Document 1, it is not possible to adjust the transmission circuit based on the collected transmission level information, so that restoration cannot be made in case malfunction has occurred due to the noise.

An interfacing device in accordance with one aspect of the present invention comprises a circuit for monitoring the level of a signal received from a node device via a transmission line, a unit for generating a packet for transferring noise information, on a monitored result, and a circuit for transmitting the packet generated over the transmission line, wherein the packet transmitted over the transmission line is transmitted to the node device either directly or through one or more of other node devices.

The interfacing device according to the present invention comprises a circuit for receiving a packet for transferring noise information, transmitted from another node device via a transmission line, and a unit for extracting the noise information from the packet and for variably controlling the output level of an output circuit configured for sending out a signal to a transmission line.

An interfacing device in accordance with another aspect of the present invention comprises a circuit for monitoring the level of a signal received from a node device via a transmission line and a circuit for variably controlling the transmission level of the output circuit based on the monitored result.

According to the present invention, a signal, such as a pulse signal, may be transmitted in place of a packet.

According to the present invention, the node device, provided with the interfacing device, constitutes a node for peer-to-peer duplex communication, a node for peer-to-peer simplex communication or a node for looped communication.

A method in accordance with another aspect of the present invention comprises the steps of:

an interfacing device monitoring the level of a signal received from a node device via a transmission line;

the interfacing device generating a packet for transferring noise information, based on the monitored result; and

the interfacing device sending out the packet generated to the transmission line. The packet transmitted over the transmission line is transmitted to the node device either directly or through one or more of other node devices.

A method according to the present invention comprises the steps of:

an interfacing device receiving a packet for transferring noise information, transmitted from another node device via a transmission line; and

the interfacing device extracting the noise information from the packet and for sending out a signal over the transmission line.

A method in accordance with a further aspect of the present invention comprises the steps of:

an interfacing device monitoring the level of a signal received from a node device via a transmission line; and

the interfacing device variably controlling an output level of an output circuit for sending out a signal to a transmission line, based on the monitored result.

The meritorious effects of the present invention are summarized as follows.

According to the present invention, in which each of the node devices connected to a network transmits a packet for transferring noise information, it is possible for any device on the network to grasp the noise information.

Moreover, according to the present invention, in which each node device adjusts the transmission level of an output circuit, using a packet for transferring noise information, the control for making transmission level adapted properly to the noise, may be achieved, so that a network may be constructed which is improved in noise immunity.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram for illustrating the configuration and the operation of a first embodiment of the present invention.

FOG. 2, similarly to FIG. 1, is a diagram for illustrating the configuration and the operation of a first embodiment of the present invention.

FIG. 3 is a diagram for illustrating a network system provided with a device of the first embodiment of the present invention.

FIG. 4, similarly to FIG. 1, is a diagram for illustrating a network system provided with a device of the first embodiment of the present invention.

FIG. 5 is a diagram for illustrating the configuration and the operation of a second embodiment of the present invention.

FIG. 6 is a waveform diagram for illustrating a modification of transmission of the noise information according to the first embodiment of the present invention.

FIG. 7 is a diagram showing a typical configuration of a conventional interfacing device.

FIGS. 8A to 8D are diagrams showing a network configuration of a conventional device.

### PREFERRED EMBODIMENTS OF THE INVENTION

The mode of practicing the present invention will now be described with reference to the drawings. An embodiment of the present invention includes a circuit (105) for monitoring the level of a signal received from a node device via a transmission line, a unit (109) for generating a packet for transferring noise information, based on a monitored result, and a circuit (102) for transmitting the packet generated over the transmission line. The packet transmitted over the transmission line is sent to the node device either directly or through one or more of other devices. According to the present invention, there are provided a circuit (104) for receiving a packet for transferring noise information which has been transmitted from another node device via a transmission line, a unit (109) for extracting the noise information from the packet, and a circuit (107) for variably controlling an output level of an output circuit (103) which sends out a signal to the transmission line.

A further embodiment of the present invention may include a circuit (105) for monitoring the level of a received signal which has been sent from a node device via a transmission line, and a circuit (107) for variably controlling an output level of an output circuit (103) which sends out a signal to the transmission line based on a monitored result. In the following, preferred embodiments of the present invention will be described in further detail.

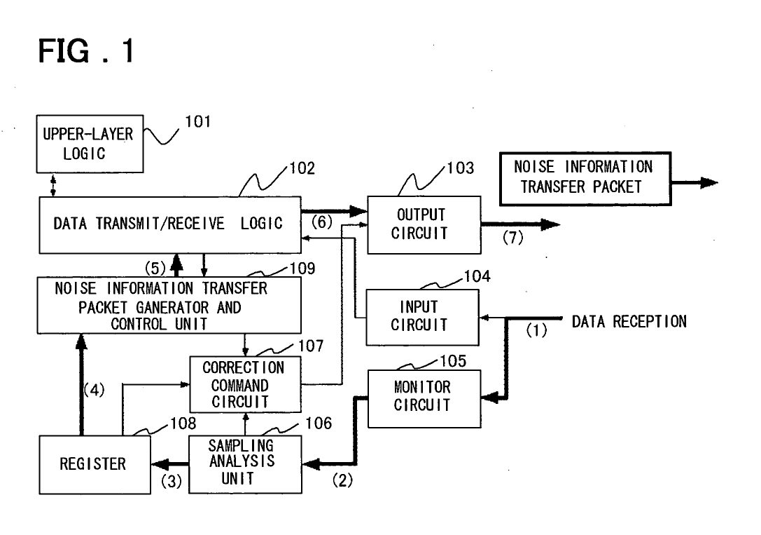

FIGS. 1 and 2 are block diagrams showing the configuration of a first embodiment of the present invention. Although FIGS. 1 and 2 show the same configuration, the processing flow, indicated by thick-lined arrows, in these figures, are not the same. Hence, FIGS. 1 and 2 are shown as distinct figures.

Referring to FIG. 1, an interfacing circuit of a first embodiment of the present invention includes an application-side upper logic 101, a data transmit/receive logic 102 for carrying out data transmission/reception, an output circuit 103, an input circuit 104, a monitor circuit 105, a sampling analysis unit 106, a correction command circuit 107, a register 108, and a noise information transfer packet generator and control unit 109.

The output circuit 103 receives a command from the correction command circuit 107 to variably set an output level or the transmission power.

The monitor circuit 105 monitors the input level of received data.

The sampling analysis unit 106 receives monitor information of the input level of received data from the monitor circuit 105 and executes sampling analysis of the monitor information of the input level of received data.

The register 108 stores the result of analysis in the sampling analysis unit 106.

The noise information transfer packet generator and control unit 109 includes a noise information transfer packet generating unit (not shown) and a control unit (not shown). The noise information transfer packet generating unit generates a noise information transfer packet, based on the result of analysis of the register 108, to supply the so generated packet to the data transmit/receive logic 102. When the input circuit 104 has received a noise information transfer packet, the control unit informs the correction command circuit 107 of the noise information, as will be described with reference to FIG. 2.

The correction command circuit 107 receives the noise information from the control unit of the noise information transfer packet generator and control unit 109 to output a command for changing the output level to the output circuit 103.

The data transmit/receive logic 102 receives the noise information transfer packet from the noise information transfer packet generator and control unit 109 to request the output circuit 103 to transmit the noise information transfer packet to a transmission line.

Referring to FIG. 1, the operation as from data monitoring up to transmission of the noise information transfer packet in the present embodiment will be described. It is noted that the serial numbers in parentheses affixed to respective thick-lined arrows of FIG. 1 stand for the serial numbers of processing operations (steps) as from data monitoring until transmission of the noise information transfer packet.

Step 1: The received data same as that supplied to the input circuit 104 is supplied to the monitor circuit 105.

Step 2: The monitor circuit 105 decides the level of the received data by a comparator circuit, not shown, and transmits the information on the result of decision to the sampling analysis unit 106.

Step 3: The sampling analysis unit 106 executes sampling analysis of the decision result information supplied from the monitor circuit 105, depending on the sampling step width, to convert the decision result information into the logic information (logic information concerning the amplitude, signal rise time, signal fall time, the signal duration time, or the like). The resulting logic information is stored in the register 108. It is preferred that, in the sampling analysis unit 106, the decision result information from the monitor circuit 105, such as sampling period or sampling step width (resolution), is set variably. Meanwhile, the monitor circuit 105 and the sampling analysis unit 106 may execute not only the time-domain analysis, for example, statistical analysis, such as time averaging of the noise, but also the frequency-domain analysis, such as calculation of frequency spectrum, in order to estimate the status of the transmission line. Or, a signal-to-noise ratio (SNR) or a bit or block error rate may be derived in order to analyze the status of the received signal.

Step 4: The noise information transfer packet generator and control unit 109 is supplied with the information stored in the register 108 (monitor result analysis information).

Step 5: For example, if the noise in the information stored in the register 108 is larger than a preset reference value, the noise information transfer packet generator and control unit 109 converts the information into that of a packet format which is predetermined on the entire network system level. Thus, a noise information transfer packet is generated and supplied to the data transmit/receive logic 102.

Step S6: The data transmit/receive logic 102 receives the noise information transfer packet and the transmit logic (not shown) of the data transmit/receive logic 102 supplies the noise information transfer packet to the output circuit 103.

Step 7: The output circuit 103 transmits the noise information transfer packet to the network.

Referring to FIG. 2, the operation as from receipt of the noise information transfer packet until adjustment of the transmission level will be described. It is noted that the numbers in parentheses affixed to respective thick-lined arrows of FIG. 2 stand for the serial numbers of processing operations (steps) as from receipt of the noise information transfer packet until adjustment of the transmission level.

Step 1: The noise information transfer packet is received. That is, the noise information transfer packet, transmitted to the transmission line from another node, is supplied to the input circuit 104.

Step 2: The input circuit 104 supplies the noise information transfer packet to the data transmit/receive logic 102.

Step 3: When the received packet is confirmed to be in compliance with the format as predetermined on the entire network, that is, when the received packet is confirmed to be a noise information transfer packet, and when the received packet is addressed to the own device, the control unit (not shown) of the noise information transfer packet generator and control unit 109 captures the noise information transfer packet.

Step 4: The noise information transfer packet generator and control unit 109 extracts the contents (noise information) from the received packet to supply the contents to the correction command circuit 107.

Step 5: The correction command circuit 107 decodes the noise information of the packet and supplies a correction command to the output circuit 103 according to the decoded result. The output circuit 103 outputs a waveform of the output level as commanded.

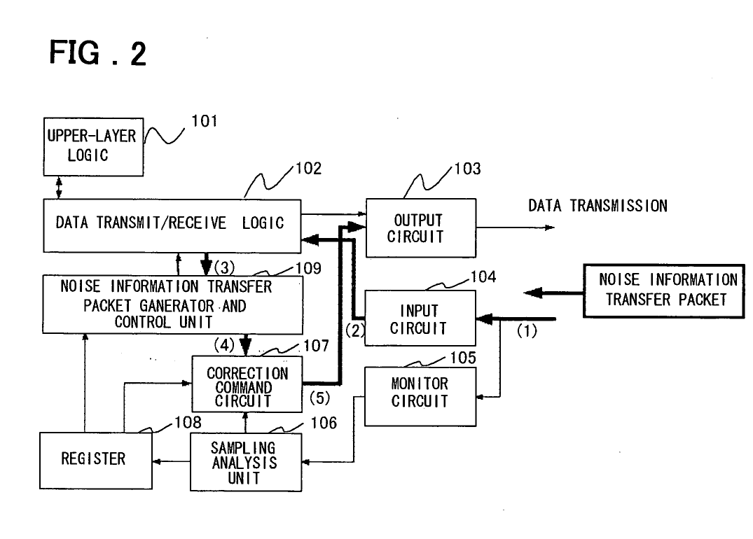

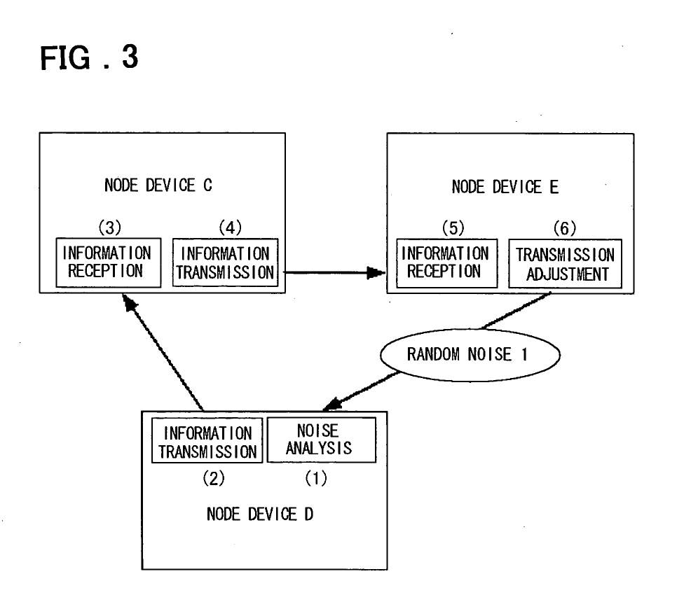

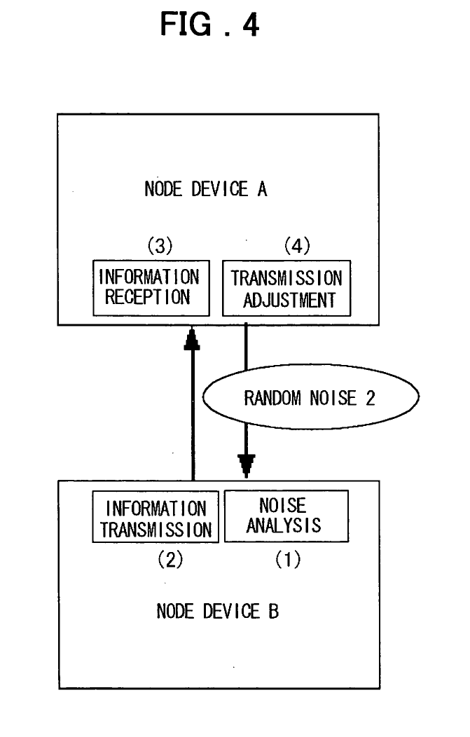

FIGS. 3 and 4 shows the configuration obtained on connecting a node device, having a transmit/receive mechanism of the first embodiment of the present invention, as described with reference to FIGS. 1 and 2. It is noted that, in FIGS. 3 and 4, the numbers in parentheses, affixed to rectangular boxes, such as a box for ‘noise analysis’, denote the numbers of the processing operations (steps) as entered in the boxes. The respective node devices are each provided with an interfacing device having the configuration as described with reference to FIGS. 1 and 2. In the following, such a case will be described in which a random noise 1 is present in a signal transmitted from the node device E to deteriorate the transmission signal, such as by waveform distortion.

The node device D executes noise analysis of the receive level (noise analysis of step 1), by the monitor circuit (105 of FIG. 1) and by the sampling analysis unit (106 of FIG. 1), and transmits the noise information transfer packet (information transmission of step 2).

The node device C receives the noise information transfer packet (information reception of step S3) to transmit the noise information transfer packet from the output circuit 103 to the node device E (information transmission of step S4). In IEEE1394, received data is automatically transmitted to another transmission line the node device is connected to.

The node device E receives the noise information transfer packet, by its input circuit 104 (information reception of step 5) to adjust the transmission level (transmission adjustment of step 6).

By the above-described sequence of operations, it becomes possible to adjust the transmission waveform so that the transmission waveform corresponds to the random noise 1, thereby realizing a stabilized network.

In case a random noise 2 is present in a signal transmitted from the node device A, as shown in FIG. 4, to deteriorate the transmission signal, such as by waveform distortion, the node device B performs the noise analysis of the receive level by the monitor circuit (105 of FIG. 1) and by the sampling analysis unit (106 of FIG. 1) (noise analysis of step 1), and transmits a noise information transfer packet (information transmission of step 2). The node device A receives the noise information transfer packet (information reception of step 3) and adjusts the transmission level (transmission adjustment of step 4).

A modification of the first embodiment of the present invention will now be described. In case it is difficult to transmit a high-speed signal by noise, the noise information transfer packet cannot be transmitted, as a result of which the network cannot be restored.

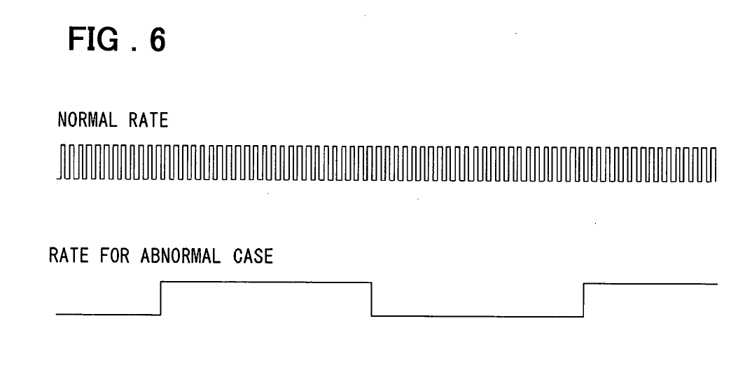

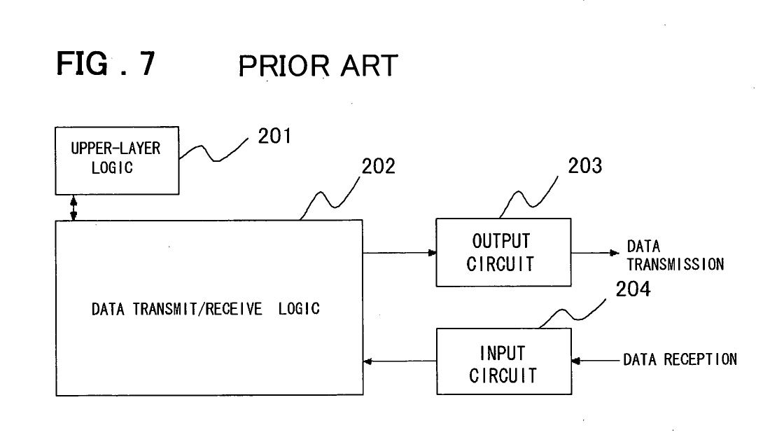

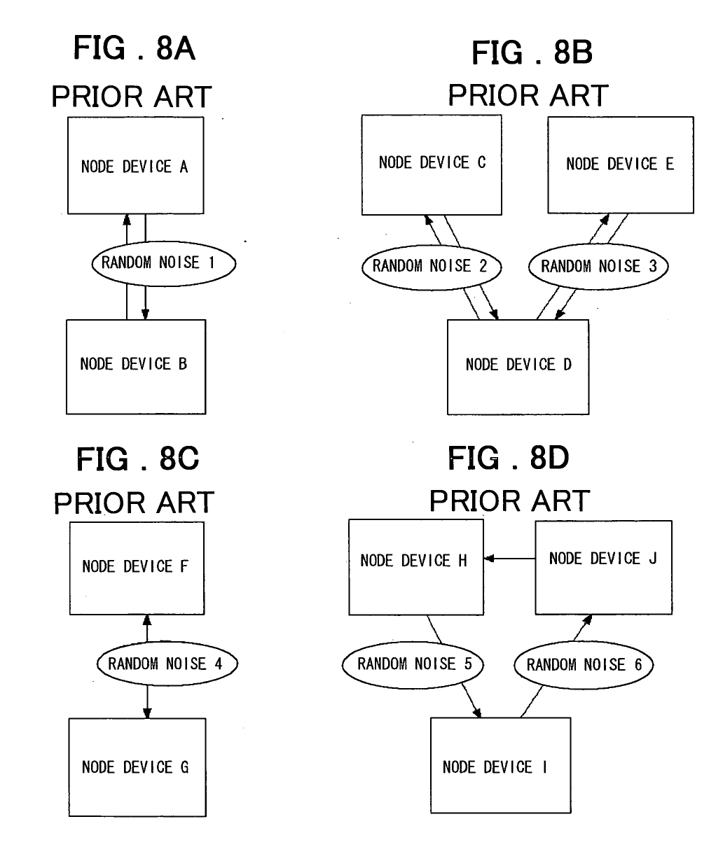

In such case, a signal (pulse signal) is sent at a predetermined low rate (rate for an abnormal case), in order to transmit the information, as shown in FIG. 6. In this case, it takes longer transmission time than in case of transferring the noise information transfer packet. However, such a network system can be constructed which is able to cope with a larger noise. If, in the above-described first embodiment, it has become difficult to transmit a high-speed signal by noise, switching may be made to the present modification (transmission of the noise information by a low-speed pulse signal).

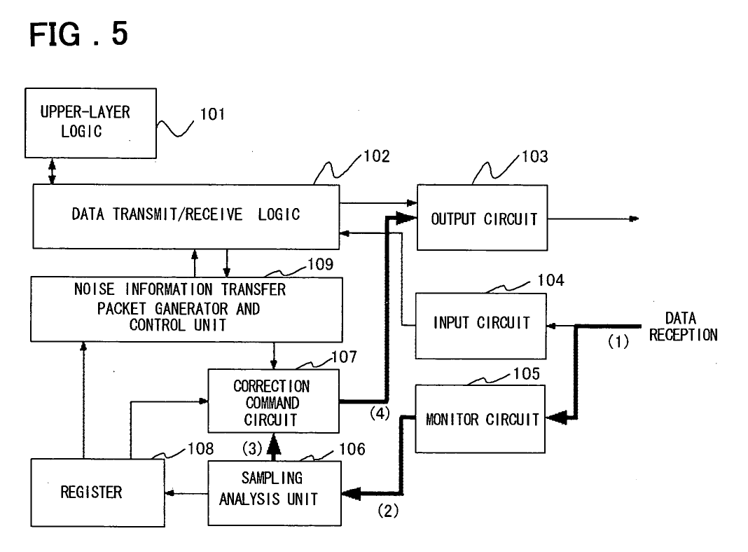

A second embodiment of the present embodiment will now be described. FIG. 5 is a block diagram showing the configuration of a second embodiment of the present invention. Although the second embodiment has a circuit configuration which is the same as that shown in FIG. 1, the two configurations differ as to the control function. That is, in the present embodiment, automatic adjustment is carried out in a node device without exploiting the noise information transfer packet. In the present second embodiment, no noise information transfer packet is generated by the noise information transfer packet generator and control unit 109, whilst no noise information is extracted from the noise information transfer packet received. Hence, the noise information transfer packet generator and control unit 109 may be omitted from FIG. 5 for the present second embodiment. It is noted that the serial numbers in parentheses affixed to respective thick-lined arrows of FIG. 5 stand for the serial numbers of processing operations (steps).

Step 1: The monitor circuit 105 monitors the input level of the received data supplied to the input circuit 104.

Step 2: The sampling analysis unit 106 analyzes the monitored result.

Step 3: The correction command circuit 107 obtains the result of analysis by the sampling analysis unit 106.

Step 4: The correction command circuit 107 issues a correction command to the output circuit 103, based on the result of analysis. The output circuit 103 changes the output level responsive to a correction command from the correction command circuit 107.

Step 4: The correction command circuit 107 may output a correction command from the analysis information of past monitored result recorded in the register 108 and from the analysis information of monitored result by the sampling analysis unit 106.

The configuration of the second embodiment of the present invention is effective in the case of peer-to-peer connection, as in the node devices A and B of FIG. 4, as an example. Since the node devices share the same transmission line (line), the node devices share the noise of relatively close characteristic in case of a short transmission distance. In this case, the information transmission of the step 2 of FIG. 4 may be dispensed with, that is, there is no necessity of transferring the noise information to the node device A. It is sufficient to adjust the transmission level of the own device, that is, the output level of the output circuit 103 of the node device B.

The second embodiment of the present invention may be implemented by a circuit configuration of a smaller size than in the case of the above-described first embodiment.

Moreover, in case the noise environment in the above-described first embodiment is changed frequently, it is necessary to increase the transmission frequency of the noise information transfer packet to perform fine adjustment. However, this affects the frequency band for normal data transmission.

With the second embodiment of the present invention, no noise information transfer packet is transmitted on the transmission line, thus not affecting normal data transmission. That is, the frequency band for data transmission may be assured.

Thus, in the first and second embodiments, in which the noise information transfer mechanism is provided in the node devices (interfacing devices) connected to the network, the noise immunity may be improved to realize a stabilized network system, in contradistinction from the conventional network system which tends to be vulnerable to the noise environment.

Although the present invention has so far been described with reference to the preferred embodiments, the present invention is not limited to the particular configurations of these embodiments. It will be appreciated that the present invention may encompass various changes or corrections such as may readily be arrived at by those skilled in the art within the scope and the principle of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. An interfacing device comprising:
a circuit for monitoring the level of a signal received from a node device via a transmission line;
a unit for generating a packet for transferring noise information, based on a monitored result; and
a circuit for sending out said packet for transferring noise information to a transmission line; wherein
said packet for transferring noise information sent out to said transmission line is transferred to said node device either directly or through one or more of other node devices.

2. The interfacing device according to claim 1, further comprising:
a circuit for receiving a packet for transferring noise information, transmitted from another node device via a transmission line;
a unit for extracting the noise information from said packet; and
a circuit for variably controlling an output level of an output circuit for sending out a signal to a transmission line, based upon the noise information.

3. The interfacing device according to claim 1, comprising:
a monitoring circuit for monitoring an input level of a signal received from said transmission line;
a sampling analysis unit for sampling and analyzing the monitored result by said monitoring circuit;
a register for recording the result of analysis of the monitored result by said sampling analysis unit;
a noise information transfer packet generating unit for generating a packet for transferring noise information, based on the result of analysis of said monitored result recorded in said register;
an output circuit for transmitting said packet to a transmission line;
an input circuit for receiving a signal from a transmission line;
a control unit for extracting noise information from said packet for transferring noise information, received from said input circuit; and
a correction command circuit for receiving the noise information from said control unit and for outputting a correction command; and
said output circuit varying an output level responsive to said correction command from said correction command circuit.

4. An interfacing device comprising:
a circuit for monitoring the level of a signal received from a node device via a transmission line; and
a circuit unit for variably controlling the output level of an output circuit for sending out a signal to a transmission line, based on the monitored result.

5. The interfacing device according to claim 4, comprising:
a monitoring circuit for monitoring an input level of a signal received from said transmission line;
a sampling analysis unit for sampling and analyzing the monitored result by said monitoring circuit;
a correction command circuit for outputting a correction command based on the result of analysis of the monitored result by said sampling analysis unit; and
an output circuit for varying the output level responsive to said correction command from said correction command circuit.

6. The interfacing device according to claim 1, comprising:
a circuit for generating a pulse signal of a rate lower than a normal rate, as a signal for transferring noise information, based on said monitored result, and for sending out said pulse signal generated to a transmission line, in lieu of sending out said packet for transferring noise information.

7. The interfacing device according to claim 6, comprising:
a circuit for receiving a pulse signal of a rate lower than a normal rate, as a signal for transferring noise information, sent out to a transmission line from another node device; and
a circuit unit for extracting the noise information from said low-rate pulse signal received and for variably controlling the output level of an output circuit for sending out a signal to a transmission line.

8. The interfacing device according to claim 1, wherein said transmission line is formed by a serial bus.

9. A node device including the interfacing device as set fourth in claim 1.

10. The node device according to claim 9, wherein said node device forms a node for peer-to-peer duplex communication, a node for peer-to-peer simplex communication or a node for looped communication.

11. A communication controlling method by an interfacing device, said method comprising the steps of:
(a) said interfacing device monitoring the level of a signal received from a node device via a transmission line;
(b) said interfacing device generating a packet for transferring noise information, based on said monitored result; and
(c) said interfacing device sending out the packet generated to said transmission packet; wherein
said packet sent to said transmission line is transferred to said node device either directly or through one or more of other node devices.

12. The method according to claim 11, further comprising the steps of:
(d) said interfacing device receiving a packet for transferring noise information, sent from another node device via a transmission line;
(e) said interfacing device extracting the noise information from said packet; and
(f) said interfacing device variably controlling an output level of an output circuit for sending out a signal to a transmission line, based upon the noise information.

13. The method according to claim 11, comprising the steps of:
(g)said interfacing device variably controlling an output level of an output circuit for sending out a signal to a transmission line, based on said monitored result, in stead of executing said steps (b) and (c).

14. The method according to claim 11, comprising the steps of:
(h)said interfacing device generating, as a signal for transferring noise information, a pulse signal of a rate lower than the normal rate and for sending out the pulse signal generated over said transmission line, in stead of executing said steps (b) and (c).

15. The method according to claim 14,comprising the steps of:
(i) said interfacing device receiving, as a signal for transferring noise information, sent from another node device via a transmission line, a pulse signal of a rate lower than a normal rate; and
(k) said interfacing device extracting the noise information from said low-rate pulse signal received and variably controlling an output level of an output circuit for sending out a signal to a transmission line.
